(19) United States
(12) Patent Application Publication
(10) Pub. No.: US 2010/0078750 A1
(43) Pub. Date: Apr. 1, 2010

(54) IMAGE SENSOR AND METHOD FOR FABRICATING THE SAME

(76) Inventor: Oh-Jin Jung, Bucheon-si (KR)

Correspondence Address: SHERR & VAUGHN, PLLC, 620 HERNDON PARKWAY, SUITE 320, HERNDON, VA, 20170, US

(21) Appl. No.: 12/568,804

(22) Filed: Sep. 29, 2009

(30) Foreign Application Priority Data
Oct. 1, 2008 (KR) 10-2008-0096408

(51) Int. Cl. H01L 31/02; H01L 31/18

(52) U.S. Cl. 257/443; 438/98; 257/E31.114

(57) ABSTRACT

An image sensor includes readout circuit arranged over a semiconductor substrate, an interlayer dielectric film covering the readout circuit and including metal lines, a buffer layer arranged over the interlayer dielectric film, a crystallized silicon layer arranged over the buffer layer, an ion-implantation layer to partition photodiode regions corresponding to unit pixels in the crystallized silicon layer, and a metal plug arranged in a via-hole of the buffer layer, to electrically connect the photodiode region to the metal lines. In accordance with the method, a channel, enabling smooth transfer of photocharges, is provided between the photodiode and the readout circuit, to minimize dark current sources and prevent a deterioration in saturation and sensitivity and thereby improve image properties.

The present application claims priority under 35 U.S.C. 119 to Korean Patent Application No. 10-2008-0096408 (filed on Oct. 1, 2008), which is hereby incorporated by reference in its entirety.

### BACKGROUND

Semiconductor devices which convert optical images into electrical signals are called image sensors. Semiconductor image sensors may be classified as charge coupled devices (CCD) and complementary metal oxide silicon (CMOS) image sensors.

In the related art, a photodiode is formed on a substrate by ion implantation. The size of photodiodes may be decreased to increase the number of pixels without increasing the size of the chips. This decrease in photodiode size causes a decrease in the area of light-receiving regions and leads to a deterioration of image quality.

In addition, the height of stacked layers does not decrease in the reduced light-receiving area. This causes a light refraction phenomenon, referred to as an Airy disk, leading to a decrease in photons impinging on a light-receiving region.

In an attempt to solve this problem, a photodiode may be deposited with amorphous silicon (Si), or a readout circuit may be formed on a silicon substrate by a method such as wafer-to-wafer bonding and a photodiode is formed on the readout circuit (hereinafter, referred to as a three-dimensional image sensor). The photodiode is connected through metal lines to the readout circuit.

In the related art, photocharges cannot be smoothly transferred between the photodiode and the readout circuit. This has disadvantages in causing dark currents, or deterioration in saturation and sensitivity.

### SUMMARY

Embodiments relate to an image sensor and a method for fabricating an image sensor which realize vertical integration between a transistor circuitry and a photodiode. Embodiments relate to an image sensor and a method for fabricating the same which may minimize or prevent leakage current. Embodiments relate to an image sensor and a method for fabricating the same in which a silicon layer to form a photodiode may be deposited over a semiconductor substrate provided with a readout circuit, and the silicon layer may be crystallized by laser irradiation.

Embodiments relate to an image sensor including a laser-absorbing layer arranged under a silicon layer to prevent the silicon layer from affecting a lower substrate during the laser-induced crystallization, and a method for fabricating the same. Embodiments relate to an image sensor and a method for fabricating an image sensor in which an impurity may be implanted into the interface of adjacent unit pixels in the silicon layer to isolate photodiodes from each other in every unit pixel.

Embodiments relate to an image sensor and a method for fabricating an image sensor in which a channel, enabling smooth transfer of photocharges, may be provided between the photodiode and the readout circuit, to minimize dark current sources and prevent deterioration in saturation and sensitivity and thereby improve image properties.

Embodiments relate to an image sensor including a readout circuit arranged over a semiconductor substrate, an interlayer dielectric film covering the readout circuit and including metal lines, a buffer layer arranged over the interlayer dielectric film, a crystallized silicon layer arranged over the buffer layer, an ion-implantation layer to partition photodiode regions corresponding to unit pixels in the crystallized silicon layer, and a metal plug arranged in a via-hole of the buffer layer, to electrically connect the photodiode regions to the metal lines.

Embodiments relate to a method for fabricating an image sensor including forming a readout circuit over a semiconductor substrate, forming an interlayer dielectric film provided with metal lines such that the interlayer dielectric film covers the readout circuit, forming a buffer layer over the interlayer dielectric film, forming a crystallized silicon layer over the buffer layer, forming a mask pattern over the silicon layer, ion-implanting an impurity into the silicon layer using the mask pattern as a mask to form an ion-implantation layer, and annealing the silicon layer using a laser to crystallize the silicon layer.

### DRAWINGS

FIGS. 1 to 7 are sectional views illustrating a process for fabricating an image sensor according to embodiments.

### DESCRIPTION

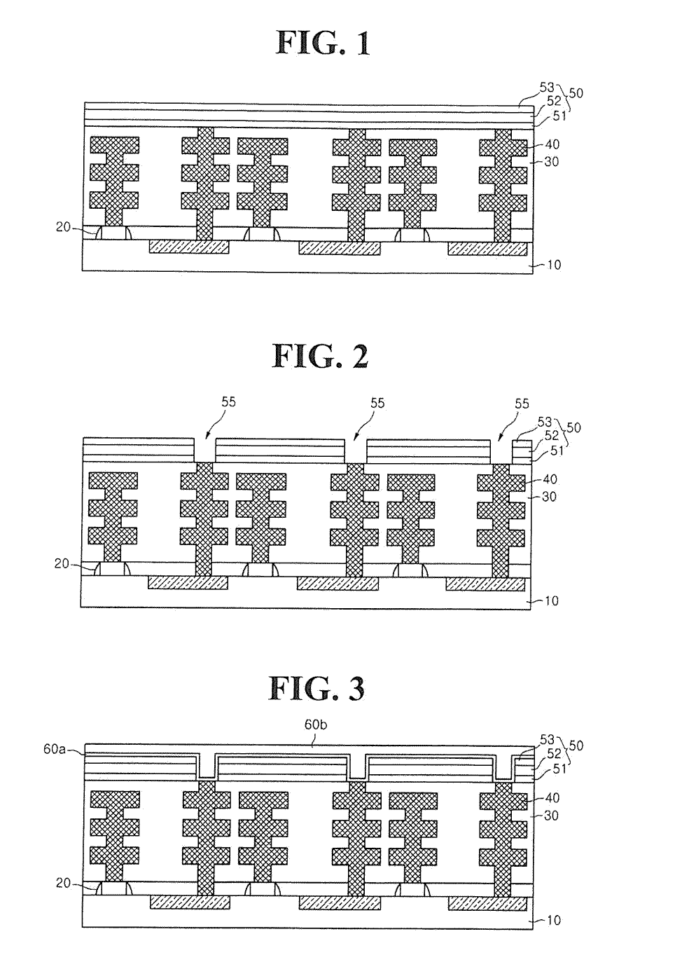

Example FIGS. 1 to 7 are sectional views illustrating a method for fabricating an image sensor according to embodiments.

As shown in example FIG. 1, an interlayer dielectric film 30 including metal lines 40 may be formed over a semiconductor substrate 10 which includes a readout circuit 20.

The readout circuit 20, connected to a photodiode which converts received photocharges into electrical signals, may be provided in each pixel unit on the semiconductor substrate 10. For example, the readout circuit 20 may be 3Tr, 4Tr or 5Tr (i.e. a three transistor readout circuit, a four transistor readout circuit, or a five transistor readout circuit). The readout circuit 20 may include a plurality of transistors. These transistors may include transfer transistors, reset transistors, drive transistors and select transistors.

In addition, the readout circuit 20 may include a floating diffusion area where impurity ions are implanted into the semiconductor substrate 100, and an active region including source/drain regions for respective transistors. A pre-metal dielectric (PMD) film may be formed over the semiconductor substrate 10 including the readout circuit 20.

The interlayer dielectric film 30 provided with metal lines 40 connected to power or signal lines may be arranged over the semiconductor substrate 10 including the readout circuit 20. The interlayer dielectric film 30 may be a multi-layer structure. For example, the interlayer dielectric film 30 may include a nitride film, an oxide film or an oxy-nitride film.

The metal lines 40 serve to transfer electric charges generated in a photodiode to the readout circuit 20 provided thereunder. The metal lines 40 may be connected to an impurity region arranged under the semiconductor substrate 10.

The metal lines 40 pass through the interlayer dielectric film 30. The metal lines 40 may be made of a variety of conductive materials including metals, alloys and silicides. For example, the metal lines 40 may be made of aluminum, copper, cobalt or tungsten.

A buffer layer 50 including a first buffer sublayer 51, a second buffer sublayer 52 and a third buffer sublayer 53 may be arranged over the interlayer dielectric film 30. The first buffer sublayer 51 may be a nitride (SiN) film, the second buffer sublayer 52 may be an oxy-nitride (SiON) film and the third buffer sublayer 53 may be a nitride (SiN) film.

The first buffer sublayer 51 may have a thickness of approximately 100 Å to 500 Å. The second buffer sublayer 52 may have a thickness of 200 Å to 1,000 Å. The third buffer sublayer 53 may have a thickness of approximately 100 Å to 500 Å. For example, the second buffer sublayer 52 may have a greater thickness than the first and third buffer layers 51 and 53, and the thickness of the first buffer sublayer 51 may be approximately equivalent to the thickness of the third buffer sublayer 53. The buffer layer 50 may further include an additional buffer layer.

The buffer layer 50 absorbs or reflects a laser pulse emitted during the subsequent excimer laser annealing. It does not transfer the excimer laser pulse to the lower interlayer dielectric film 30 and the metal lines 40. As a result, the buffer layer 50 serves as a laser-absorbing layer (or laser-reflecting layer) to prevent a laser from being irradiated to a lower substrate during the excimer laser annealing, and protects the lines and transistors.

As shown in example FIG. 2, the buffer layer 50 may be patterned to form a via-hole 55 through which the metal lines 40 are exposed. A photoresist film may be formed over the buffer layer 50 and is selectively exposed to light to form a photoresist pattern. The buffer layer 50 may be selectively etched using the photoresist pattern as a mask. The photoresist pattern may then be removed.

As shown in example FIG. 3, a barrier film 60a may be deposited over the buffer layer 50. A metal film 60b may be formed over the barrier film 60a. The barrier film 60a may be formed over the upper surface of the upper dielectric pattern 57 along an inner side of the via-hole and comes in contact with metal lines 40 exposed by the via-hole.

The barrier film 60a may be made of at least one selected from the group consisting of Ta, TaN, TaAlN, TaSiN, Ti, TiN, WN, TiSiN and TCu. The barrier film 60a may be in the form of a double-layer, e.g., Ti film/TiN film. The barrier film 60a may have a thickness of approximately 50 Å to 300 Å. The metal film 60b may include at least one selected from the group consisting of aluminum, titanium, copper, tungsten and aluminum alloys. The metal film 60b may be arranged in the via-hole and connected electrically to the metal lines 40 through the barrier film 60a.

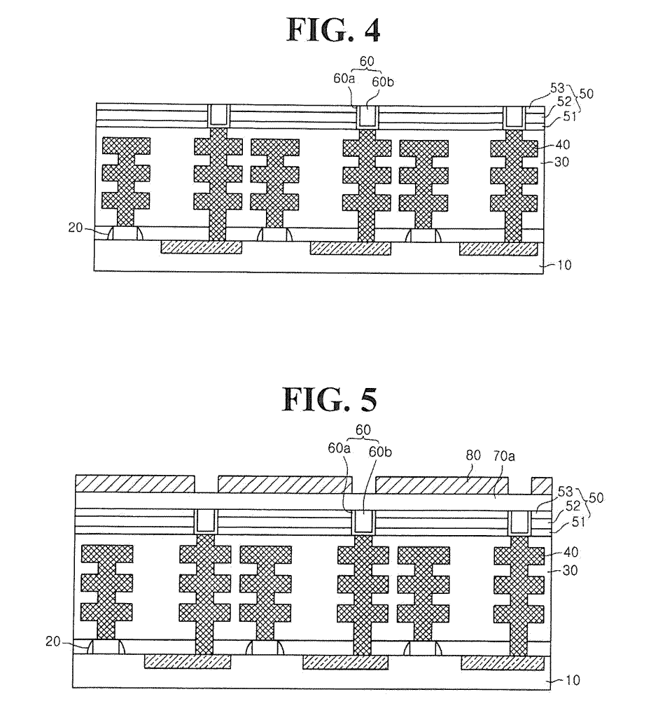

As shown in example FIG. 4, the metal film 60b may be polished by chemical mechanical polishing (CMP) such that the surface of the upper dielectric pattern 57 is exposed. As a result, patterns for the barrier film 60a and the metal film 60b may be formed in the via-hole to form a plug 60 to connect the metal lines 40 to the plug 60 in the subsequent process. Plug 60 may be provided in each pixel unit.

As shown in example FIG. 5, a silicon layer 70a may be deposited over the buffer layer 50 and the plug 60. The silicon layer 70a may have a thickness of approximately 3,000 Å to 5,000 Å.

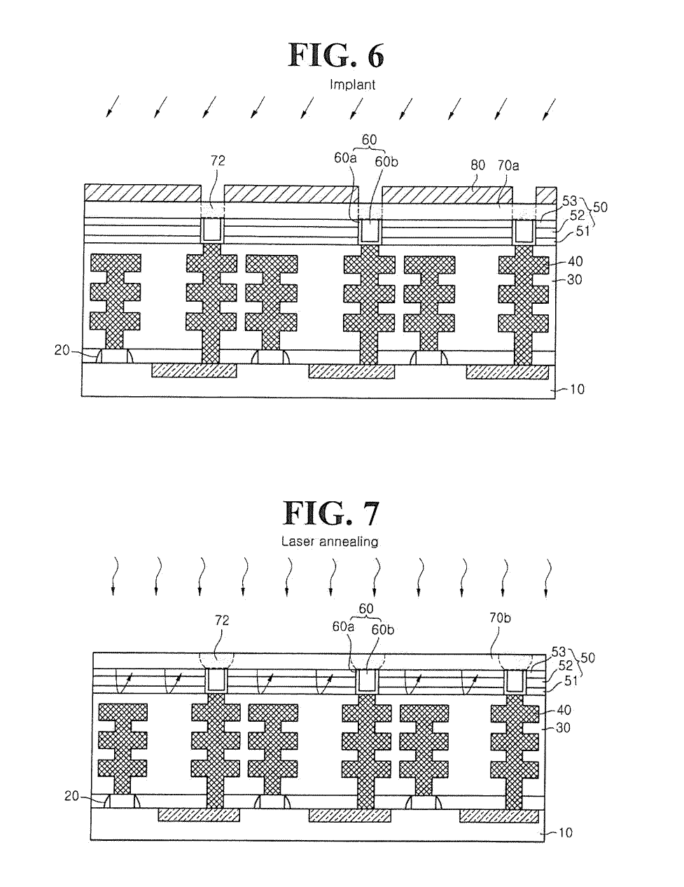

As shown in example FIG. 6, a mask pattern 80 may be formed over the silicon layer 70a. An impurity may be ion-implanted into the mask pattern 80 using the mask pattern 80 as a mask to form an ion-implantation region 72. The impurity may be a Group III element. For example, the impurity may be boron. The ion-implantation may be carried out at an angle with respect to the upper surface of the silicon layer 70a. Alternatively, the ion-implantation may be carried out at right angles to the upper surface of the silicon layer 70a.

The ion-implantation region 72 is formed over the interface of adjacent respective pixel units, to separate the pixel units from each other. The ion-implantation may be carried out using boron (11B+) at an energy of approximately 15 KeV to 350 KeV at a dose of approximately 1×10¹² to 1×10¹³ atoms/cm².

As shown in example FIG. 7, the silicon layer 70a including the ion-implantation region 72 may be annealed by excimer laser irradiation to form a crystallized silicon layer 70b. The excimer laser annealing may be carried out at a wavelength of approximately 1,000 to 1,500 nm for 1 to 10 seconds at an energy of approximately 2 J/cm² to 10 J/cm². Accordingly, photoelectrons generated in photodiode regions partitioned by the ion-implantation region 72 may be transferred through the plug 60 and the metal lines 40 to a lower substrate.

The excimer laser annealing may be carried out after removing the mask pattern 80 to form the ion-implantation region 72 over the silicon layer 70a. During the excimer laser annealing, the ion-implantation region 72 may be diffused into an adjacent region, A color filter and microlens may be formed over the crystallized silicon layer 70b.

In accordance with embodiments, adjacent unit pixels may be isolated from each other to improve noise properties, and no etching process is necessary, thus improving process stability and simplifying the overall process. In accordance with embodiments, a silicon layer to form a photodiode may be deposited over a semiconductor substrate 10 provided with a readout circuit 20. A laser absorbing layer is provided thereunder to protect the lower substrate during crystallization using a laser. In accordance with embodiments, a channel, enabling smooth transfer of photocharges, is provided between the photodiode and the readout circuit, to minimize dark current sources and prevent deterioration in saturation and sensitivity and thereby improve image properties.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a readout circuit arranged over a semiconductor substrate;
an interlayer dielectric film, including metal lines, covering the readout circuit;
a buffer layer arranged over the interlayer dielectric film;
a crystallized silicon layer arranged over the buffer layer;
at least one ion-implantation region in the crystallized silicon layer to partition the crystallized silicon layer into photodiode regions corresponding to unit pixels; and
a metal plug arranged in a via-hole of the buffer layer, to electrically connect the photodiode regions to the metal lines.

2. The apparatus of claim 1, wherein the metal lines are electrically connected to the readout circuit.

3. The apparatus of claim 1, wherein the at least one ion-implantation region is formed by ion-implanting a Group III element.

4. The apparatus of claim 1, wherein the at least one ion-implantation region is formed on the interface of adjacent unit pixels.

5. The apparatus of claim 1, wherein the buffer layer includes a plurality of sublayers.

6. The apparatus of claim 5, wherein the buffer layer includes a first buffer sublayer made of a nitride film.

7. The apparatus of claim 6, wherein the buffer layer includes a second buffer sublayer made of oxy-nitride film.

8. The apparatus of claim 7, wherein the buffer layer includes a third buffer sublayer made of a nitride film.

9. The apparatus of claim 8, wherein the second buffer sublayer has a greater thickness than the thickness of the first buffer sublayer and the third buffer sublayer.

10. The apparatus of claim 9, wherein the thickness of the first buffer sublayer is equivalent to the thickness of the third buffer sublayer.

11. A method comprising:
forming a readout circuit over a semiconductor substrate;
forming an interlayer dielectric film, including metal lines, such that the interlayer dielectric film covers the readout circuit;
forming a buffer layer over the interlayer dielectric film;
forming a silicon layer over the buffer layer;
forming a mask pattern over the silicon layer;
ion-implanting an impurity into the silicon layer using the mask pattern as a mask to form an ion-implantation region to partition a unit pixel; and
annealing the silicon layer using a laser to crystallize the silicon layer, thereby forming a crystallized silicon layer.

12. The method of claim 11, further comprising:
forming a via-hole in the buffer layer such that the via-hole exposes the metal lines;
forming a barrier film and a metal film over the buffer layer including the via-hole; and
polishing the metal film to form a metal plug in the buffer layer.

13. The method of claim 11, wherein the step of forming the buffer layer comprises:
forming a first buffer sublayer made of a nitride film over the interlayer dielectric film;
forming a second buffer sublayer made of an oxy-nitride film over the first buffer sublayer; and
forming a third buffer sublayer made of a nitride film over the second buffer sublayer.

14. The method of claim 13, wherein the second buffer sublayer is formed to a greater thickness than the first buffer sublayer and the third buffer sublayer.

15. The method of claim 13, wherein the first and third buffer sublayers are formed such that the thickness of the first buffer sublayer is equivalent to the thickness of the third buffer sublayer.

16. The method of claim 11, wherein the formation of the ion-implantation region is carried out by ion-implanting a Group III element into the silicon layer.

17. The method of claim 16, wherein the ion-implantation is carried out using boron (11B+) at an energy of 15 KeV to 350 KeV.

18. The method of claim 17, wherein the ion-implantation is carried out using a dose of 1×10¹² to 1×10¹³ atoms/cm².

19. The method of claim 11, wherein the crystallization of the silicon layer is carried out with an excimer laser at a wavelength of 1,000 to 1,500 nm.

20. The method of claim 19, wherein the crystallization of the silicon layer is carried out for 1 to 10 seconds at an energy of 2 J/cm² to 10 J/cm².
